(19) United States
(12) Patent Application Publication
(10) Pub. No.: US 2024/0264393 A1
(43) Pub. Date: Aug. 8, 2024

(54) SILICON PHOTONICS PACKAGE, METHOD OF MANUFACTURING THE SAME, AND SWITCH PACKAGE

(71) Applicant: Samsung Electronics Co., Ltd., Suwon-si (KR)

(72) Inventors: Seok Geun Ahn, Suwon-si (KR); Haseob Seong, Suwon-si (KR)

(21) Appl. No.: 18/235,518

(22) Filed: Aug. 18, 2023

(30) Foreign Application Priority Data
Feb. 6, 2023 (KR) 10-2023-0015563

(51) Int. Cl. G02B 6/42

(52) U.S. Cl. CPC G02B 6/428; G02B 6/4249; G02B 6/4293

(57) ABSTRACT

Disclosed is a silicon photonics package including an interposer including embedded optical components; a light source element optically connected to the optical components; a first semiconductor chip on a top surface of the interposer; a first redistribution layer on a bottom surface of the interposer; a second semiconductor chip on the first redistribution layer; a second redistribution layer on the first redistribution layer and being electrically connected to the first redistribution layer; conductive metal posts provided between the first and second redistribution layers; a mold material filling a space between the first and second redistribution layers; and a solder bump array on a bottom surface of the second redistribution layer. The top surface of the interposer includes an exposure area to which an optical fiber array is directly attached, in which an optical signal is directly transmitted between the optical components and the optical fiber array through the exposure area.

### CROSS-REFERENCE TO RELATED APPLICATION

This application claims priority to and the benefit under 35 U.S.C. § 119 of Korean Patent Application No. 10-2023-0015563, filed on Feb. 6, 2023, in the Korean Intellectual Property Office, the entire contents of which are incorporated herein by reference.

### BACKGROUND OF THE INVENTION

### (a) Field of the Invention

The present disclosure relates to a silicon photonics package, a method of manufacturing the same, and a switch package including the silicon photonics package.

### (b) Description of the Related Art

As data traffic rapidly increases, there is an increasing need to reduce power consumption of a data center and improve a degree of integration of a system. In the related art, an optical signal, instead of an electrical signal, has been used for communication between the data centers, and thus a demand for optical transceivers has rapidly increased.

Silicon photonics is an optical semiconductor made by implementing optical components for transmitting and receiving optical signals on a silicon-based die by a semiconductor process. The silicon photonics may be stably mass-produced at low cost by a mature silicon process and have high-performance characteristics reliable from 25 Gbps to 100 Gbps. In addition, because the silicon photonics has low power consumption and signal integrity characteristics, the silicon photonics is used to implement a low-power package by being coupled to an electronic element.

Meanwhile, there has been an effort to minimize an electrical signal path even in the data center, and there has been proposed a configuration in which an optical transceiver and a switch ASIC chip are mounted on the same substrate.

The silicon photonics package, as the optical transceiver, is a module made by forming optical components directly on a silicon-based die through a CMOS process and integrating electronic components together that perform a conversion process between the optical signal and the electrical signal. Because the silicon photonics packages are applied to very wide and diverse application fields, there is a need for designs at various levels.

The above information disclosed in this Background section is only for enhancement of understanding of the background of the invention, and therefore it may contain information that does not form the prior art that is already known in this country to a person of ordinary skill in the art.

### SUMMARY OF THE INVENTION

The present disclosure has been made in an effort to provide a silicon photonics package, which is capable of being manufactured at a wafer level and having a structure to which an optical fiber array is easily attached, a method of manufacturing the same, and a switch package including the silicon photonics package.

According to a first aspect of the present disclosure, there is provided a silicon photonics package. The silicon photonics package includes: an interposer including embedded optical components and a plurality of through silicon vias (TSVs); a light source element optically connected to the optical components; a first semiconductor chip mounted on a top surface of the interposer; a first redistribution layer provided on a bottom surface of the interposer; a second semiconductor chip mounted on the first redistribution layer; a second redistribution layer disposed to be facing the first redistribution layer with the second semiconductor chip interposed therebetween, the second redistribution layer being electrically connected to the first redistribution layer; conductive metal posts provided between the first redistribution layer and the second redistribution layer; a mold material with which a space between the first redistribution layer and the second redistribution layer is filled; and a solder bump array provided on a bottom surface of the second redistribution layer, in which the top surface of the interposer includes an exposure area to which an optical fiber array is directly attached, in which an optical signal is directly transmitted between the optical components and the optical fiber array through the exposure area, and in which the first semiconductor chip and the second semiconductor chip include electronic components configured to perform electronic processing for transmitting a signal between the optical components and an external device.

In the embodiment, the interposer may include a photonic area provided at the top surface thereof, the photonic area may be optically isolated and define at least a part of the top surface of the interposer, the optical components may be provided in the photonic area, and the exposure area may be at least a part of the photonic area.

In the embodiment, connection terminals may be provided on a top surface of the photonic area and electrically connected to some of the optical components, the first semiconductor chip may be mounted to cover at least a part of the photonic area, and the first semiconductor chip may be electrically connected to the connection terminals through at least a part of the solder bump array.

In the embodiment, the first semiconductor chip may be configured to receive an electrical signal from some of the optical components and transmit the received electrical signal to the second semiconductor chip through the plurality of through silicon vias (TSV).

In the embodiment, the optical components may include a grating coupler, an optical modulator, an optical waveguide, and a photodetector.

In the embodiment, the electronic components may include a logic circuit configured to amplify an electrical signal from the photodetector to output the electrical signal to an outside, and operate the optical modulator in response to an electrical signal inputted from the outside.

In the embodiment, the first semiconductor chip may include a part of the logic circuit, and the second semiconductor chip may include a remaining part of the logic circuit. In the embodiment, the logic circuit may include a trans-impedance amplifier configured to convert the electrical signal from the photodetector into a voltage signal, an output driver configured to output the converted electrical signal to the outside, an input buffer configured to receive an electrical signal from the outside, a controller configured to control the light source element, and a modulator driver configured to operate the optical modulator, and the second semiconductor chip may at least include the output driver and the input buffer.

In the embodiment, the photonic area may include a buried oxide layer, and a silicon layer stacked on the buried oxide layer, and the optical components may be provided by patterning the silicon layer.

In the embodiment, the first semiconductor chip may include a transistor array.

In the embodiment, a diameter of each of the plurality of through silicon vias may be 0.5 to 30 μm, a pitch of the plurality of through silicon vias may be 1 to 60 μm, and a height of each of the plurality of through silicon vias may be 5 to 300 μm.

In the embodiment, a diameter of each of the metal posts may be 5 to 300 μm, a pitch of the metal posts may be 10 to 600 μm, and a height of each of the metal posts may be 50 to 1,000 μm.

In the embodiment, the light source element may be mounted on a top surface of a photonic area.

In the embodiment, the light source element may be disposed in a groove provided in the interposer.

According to a second aspect of the present disclosure, there is provided a method of manufacturing a silicon photonics package. The method includes: providing optical components embedded at a top surface of an interposer and providing a plurality of through silicon vias (TSVs) in the interposer; flipping the interposer and bonding the interposer to a wafer by means of a carrier tape; grinding a bottom surface of the interposer and providing a first redistribution layer on the bottom surface of the interposer; providing metal posts on the first redistribution layer and attaching a second semiconductor chip; providing a molding material to surround the metal posts and the second semiconductor chip; grinding a surface of the molding material and providing a second redistribution layer on the surface of the molding material; providing a solder bump array on the second redistribution layer; attaching a mounting tape to a side at which the solder bump array is provided and removing the carrier tape; and attaching a first semiconductor chip and a light source element onto the top surface of the interposer, in which at least some of the optical components are configured to directly transmit or receive an optical signal to or from an optical fiber array through a part of the top surface of the interposer, and in which the first semiconductor chip and the second semiconductor chip include electronic components configured to perform electronic processing for transmitting a signal between the optical components and an external device.

In the embodiment, the providing optical components embedded at the top surface of the interposer may include: providing a buried oxide layer on the top surface of the interposer and providing an optically isolated photonic area by stacking a silicon layer on the buried oxide layer; and providing the optical components by patterning the silicon layer.

In the embodiment, the first semiconductor chip may include a transistor array.

In the embodiment, a plurality of silicon photonics packages may be manufactured at a wafer level, and the method may further include: providing a protective layer configured to cover the top surface of the interposer after the removing of the carrier tape; singularizing the silicon photonics package by dicing; and removing the protective layer.

According to a third aspect of the present disclosure, there is provided a switch package. The switch package includes: a substrate; a switch application specific integrated circuit (ASIC) chip mounted at a central portion of the substrate; and a plurality of optical transceivers mounted at a periphery of the switch ASIC chip, in which the switch ASIC chip and the plurality of optical transceivers are electrically connected through an electrical circuit of the substrate, in which the optical transceivers each include: an interposer including embedded optical components and a plurality of through silicon vias (TSVs); a light source element optically connected to the optical components; a first semiconductor chip mounted on a top surface of the interposer; a first redistribution layer provided on a bottom surface of the interposer; a second semiconductor chip mounted on the first redistribution layer; a second redistribution layer disposed to be facing the first redistribution layer with the second semiconductor chip interposed therebetween, the second redistribution layer being electrically connected to the first redistribution layer; conductive metal posts provided between the first redistribution layer and the second redistribution layer; a mold material with which a space between the first redistribution layer and the second redistribution layer is filled; and a solder bump array provided on a bottom surface of the second redistribution layer and electrically connected to the substrate, in which the top surface of the interposer includes an exposure area to which an optical fiber array is directly attached, in which an optical signal is directly transmitted between the optical components and the optical fiber array through the exposure area, and in which the first semiconductor chip and the second semiconductor chip include electronic components configured to perform electronic processing for transmitting a signal between the optical components and an external device.

In the embodiment, the switch package may further include: an optical fiber interface including an optical coupler optically connected to the exposure area of the interposer, and an optical connector to which the optical fiber array is connected.

According to the embodiments of the present disclosure, it is possible to obtain the silicon photonics package capable of being manufactured at the wafer level and having the configuration to which the optical fiber array is easily attached. Therefore, the switch package including the silicon photonics package may be manufactured to be small in scale and have a high bandwidth and high-performance characteristics.

### BRIEF DESCRIPTION OF THE DRAWINGS

FIG. 1 is a schematic top plan view of a switch package.

FIG. 2 is a cross-sectional view of a silicon photonics package.

FIG. 3 is a schematic block diagram illustrating constituent elements of the silicon photonics package according to example embodiments of the present disclosure.

FIG. 4 is a view illustrating an example of optical components according to example embodiments of the present disclosure.

FIG. 5 is a cross-sectional view of a silicon photonics package according to example embodiments of the present disclosure.

FIGS. 6A to 6D are views illustrating a method of manufacturing the silicon photonics package according to example embodiments of the present disclosure.

FIG. 7 is a cross-sectional view of the package according to example embodiments of the present disclosure.

FIG. 8 is a cross-sectional view of a switch package according to example embodiments of the present disclosure.

FIG. 9 is a schematic cross-sectional view of a device according to example embodiments of the present disclosure.

### DETAILED DESCRIPTION OF THE EMBODIMENTS

Hereinafter, example embodiments of the present disclosure will be described in detail with reference to the accompanying drawings so that those with ordinary skill in the art to which the present disclosure pertains may easily carry out the embodiments. The present disclosure may be implemented in various different ways and is not limited to the embodiments described herein.

A part irrelevant to the description will be omitted to clearly describe the present disclosure, and the same or similar constituent elements will be designated by the same reference numerals throughout the specification.

In addition, a size and thickness of each constituent element illustrated in the drawings are arbitrarily shown for convenience of description, but the present disclosure is not limited thereto. In order to clearly describe several layers and regions, thicknesses thereof are enlarged in the drawings. In the drawings, the thicknesses of some layers and regions are exaggerated for convenience of description.

In addition, when one component such as a layer, a film, a region, or a plate is described as being positioned “above” or “on” another component, one component can be positioned “directly on” another component, and one component can also be positioned on another component with other components interposed therebetween. On the contrary, when one component is described as being positioned “directly above” another component, there is no component therebetween. In addition, when a component is described as being positioned “above” or “on” a reference part, the component may be positioned “above” or “below” the reference part, and this configuration does not necessarily mean that the component is positioned “above” or “on” the reference part in a direction opposite to gravity.

Throughout the specification, unless explicitly described to the contrary, the word “comprise/include” and variations such as “comprises/includes” or “comprising/including” will be understood to imply the inclusion of stated elements, not the exclusion of any other elements.

Throughout the specification, the word “in a plan view” means when an object is viewed from above, and the word “in a cross-sectional view” means when a cross section made by vertically cutting an object is viewed from a lateral side.

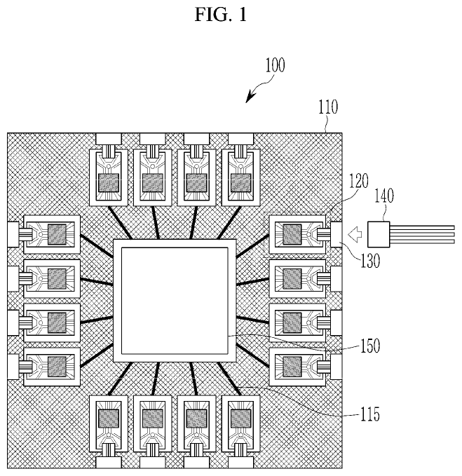

FIG. 1 is a top plan view of a structure of a switch package.

A switch package 100 is mainly used for a data center. A plurality of silicon photonics packages 120 are disposed at the periphery of a switch ASIC chip 150 to process a large amount of data traffic at high speed.

The connection between the silicon photonics package 120 and the switch ASIC chip 150 is implemented by an electrical signal path 115. The electrical signal path 115 is formed by conductive connection members formed in a substrate 110 and/or on the substrate 110. Because the silicon photonics package 120 and the switch ASIC chip 150 are mounted on the same substrate 110, the electrical signal path is comparatively short. Because the electrical signal path is short, an optical signal path may be lengthened, which makes it possible to obtain more efficient power consumption and a higher bandwidth.

An optical fiber interface 130 is connected to the silicon photonics package 120. The optical fiber interface 130 connects an optical fiber array 140 to the switch package 100. The optical fiber array 140 may be attached directly to the silicon photonics package 120. However, the optical fiber interface 130 facilitates a process of assembling the switch package 100 into a system and then connecting the optical fiber array 140. The optical fiber interface 130 includes an optical coupler coupled to the optical components of the silicon photonics package 120, and an optical fiber connector connected to the optical fiber array 140. The optical fiber connector may be a plug type or fixed to the substrate 110. The optical fiber interface 130 will be described below.

In the related art, an optical transceiver and a switch ASIC chip are disposed on the same system board or panel. As illustrated in FIG. 1, when the switch ASIC chip and the optical transceiver are packaged together on the same substrate, the electrical signal path may be further shortened. To this end, the optical transceiver may be further miniaturized.

The silicon photonics is manufactured by directly forming optical components directly in a silicon-based die through a CMOS process. A photonic integrated circuit (PIC, photonic IC) includes optical components formed at a wafer level. The silicon photonics package is obtained by attaching a laser diode or the like, as a light source element, onto the PIC, and attaching an electronic integrated circuit (EIC, electronic IC) including electronic components that perform the conversion between the optical signal and the electrical signal and the process for inputting and outputting the electrical signal.

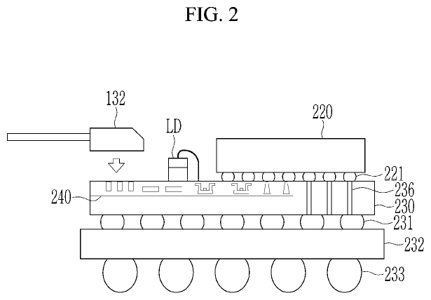

FIG. 2 is a cross-sectional view of a silicon photonics package.

A photonic integrated circuit (PIC) 230 is mounted on a substrate 232 through a solder bump array 231. An electronic integrated circuit (EIC) 220 is mounted on a top surface of the photonic integrated circuit (PIC) 230 through a solder bump array 221. The solder bump array 231 may be a C4 (controlled collapse chip connection) bump array. The solder bump array 221 may be configured as an array of micro bumps or copper (Cu) pillar bumps.

A solder bump array 233 formed on a bottom surface of the substrate 232 implements physical coupling and electrical connection when mounting the silicon photonics package on another system board or the like.

Through silicon vias (TSVs) 236 may be formed in the PIC 230. The EIC 220 may be electrically connected to an external device through the through silicon vias (TSVs). In addition, because the through silicon via is formed, a necessity of bonding a separate power supply wire is eliminated, and a package having a smaller form factor may be realized.

A photonic area 240 is formed on a top surface in the PIC 230. The optical components are formed in the photonic area 240. The optical components may be formed by the CMOS process. The photonic area 240 defines an optically isolated area. The optical components are configured to convert optical signals received through the optical fiber array into electrical signals and transmit the electrical signals to the electronic components. The optical components are configured to transmit optical signals, which are emitted from a light source element LD, through the optical fiber array under the control of the electronic components.

The light source element LD is attached to the top surface of the photonic area 240 of the PIC 230. The light source element LD may be a laser diode. For example, the light source element LD generates visible light or near-infrared rays. The drawings in the present disclosure illustrate that the light source element LD is attached to the top surface of the photonic area 240. However, the light source element LD may be disposed in a groove formed on the top surface of the photonic area 240. Alternatively, a laser diode may be directly grown on the PIC 230.

The light source element LD is optically connected to the optical components while being electrically connected to the PIC 230 at the same time. The light source element LD emits a light in response to a control signal from the electronic components, and the emitted light enters an optical waveguide through a light spot size converter. The light introduced into the optical waveguide is transmitted through the optical fiber array via an optical modulator.

An optical coupler 132 is attached onto the photonic area 240 and implements optical connection between the optical fiber array and the optical components. The optical coupler 132 is attached to the top surface of the photonic area 240 after the silicon photonics package is mounted on the system board or the like through the solder bump array 233. However, the present disclosure is not limited thereto. In addition, the drawings of the present disclosure illustrate that the optical coupler 132 is attached to the top surface of the photonic area 240, but the present disclosure is not limited thereto. Various technologies may be adopted for optical connection between the optical components and the optical fiber array. For example, the optical coupler 132 may be attached to a sidewall of the photonic area 240, and the light may be transmitted or received through an edge instead of the top surface of the photonic area 240. In addition, the type of the optical coupler 132 is not limited. For example, a plurality of V-shaped grooves (V-grooves) may be formed on the top surface of the photonic area 240, the optical fibers may be respectively disposed in the V-shaped grooves and fixed by a bonding agent, and the optical fibers may be covered by a polymer cover, such that the optical fiber array may be attached to the photonic area 240.

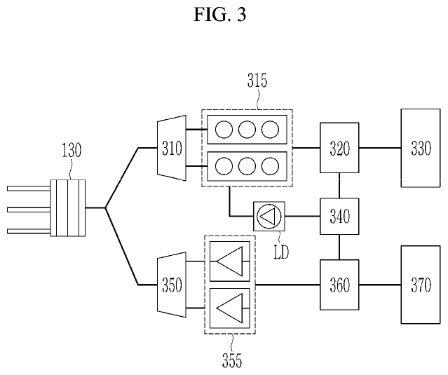

FIG. 3 is a schematic block diagram illustrating constituent elements of the silicon photonics package according to example embodiments.

The optical fiber interface 130 is an input/output port for an optical signal between the optical fiber array and the silicon photonics package. The respective elements will be described with reference to a case in which the optical signal is received and a case in which the optical signal is transmitted.

The optical signal received through the optical fiber interface 130 reaches a plurality of photodetectors 355 through a demultiplexer (DEMUX) 350. The photodetectors 355 convert an optical signal into an analog electrical signal. The trans-impedance amplifier (TIA) 360 converts an electric current signal from the photodetector 355 into a voltage signal. The converted electrical signal is outputted to the outside through an output driver 370.

When an input buffer 330 receives an electrical signal, the light source element LD emits light on the basis of the received electrical signal, and the modulator driver 320 operates a plurality of optical modulators 315 to modulate the light emitted from the light source element LD. The electronic components including the light source element LD operate under the control of a controller 340. The modulated light is transmitted to the optical fiber interface 130 through the multiplexer 310, and the optical signal is transmitted through the optical fiber array connected to the optical fiber interface 130.

The silicon photonics package may include more optical components and more electronic components in addition to the elements described above. However, it should be understood that for convenience of description, only the main elements have been introduced.

In FIG. 3, the multiplexer 310, the plurality of optical modulators 315, the demultiplexer 350, and the plurality of photodetectors 355 are optical components, and the trans-impedance amplifier 360, the output driver 370, the input buffer 330, the modulator driver 320, and the controller 340 are electronic components.

Typically, the optical components are included in the PIC, and the electronic components are included in the EIC. However, the present disclosure is not necessarily limited thereto. Because the PIC is manufactured by the CMOS process, the PIC may include some of the electronic components as well as the optical components. The trans-impedance amplifier 360, the output driver 370, the input buffer 330, the modulator driver 320, and the controller 340 are merely classifications of the electronic components depending on their functions. This classification is not necessarily identical to the physical division. The electronic components are implemented by a transistor array, and the PIC may include a part of the transistor array.

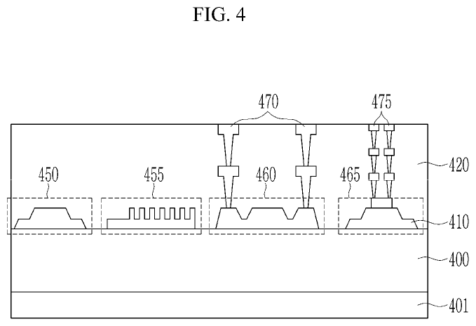

The optical components will be more specifically described with reference to FIG. 4.

FIG. 4 is a view illustrating an example of optical components according to example embodiments.

Referring to FIG. 4, a buried oxide layer (BOX layer) 400 is formed on a silicon-based member 401. The buried oxide layer 400 defines a boundary of the photonic area (e.g., photonic area 240 of FIG. 3). The buried oxide layer 400 may be formed over an entire top surface of the silicon-based member 401 or formed on only a part of the top surface of the silicon-based member 401. A silicon layer is stacked on the buried oxide layer 400. A patterned silicon layer 410 is formed by patterning the silicon layer through a lithography process and an etching process. The patterned silicon layer 410 constitutes the optical components. A cladding layer 420 is stacked on the patterned silicon layer 410. Although not illustrated, a nitride layer may be formed on the patterned silicon layer 410.

The patterned silicon layer 410 defines an optical waveguide 450, a grating coupler 455, an optical modulator 460, and a photodetector 465, as the optical components.

The optical waveguide 450 has high internal reflectance and implements an optical path that confines and transmits light. The optical waveguide 450 is optically connected to other optical components. The optical waveguide 450 may be provided as a single structure or a plurality of structures. For example, the optical waveguide 450 may be formed by forming a nitride layer and patterning the nitride layer.

The grating coupler 455 is a medium that receives the optical signal transmitted from the outside through the optical fiber array or transmits the optical signal to the outside through the optical fiber array. The grating coupler 455 is optically connected to the optical waveguide 450. In the present embodiment, the grating coupler 455 is disclosed. However, those skilled in the art will easily understand that an edge coupler may be used. In case that the edge coupler is used, the light is horizontally transmitted or received through the edge instead of being transmitted or received vertically toward the top surface of the photonic area.

The optical modulator 460 modulates the light, which is emitted from the light source element, according to the signal intended to transmit the light, and converts the light into an optical signal having information. For example, the optical modulator 460 is a phase modulator. In some embodiments, the optical modulator 460 may be, but is not limited to, any one of a Mach-Zehnder modulator, a micro-ring modulator, an electro-absorption modulator (EAM), an LN/Si hybrid modulator, and a TFLN (thin-film lithium niobate) optical modulator.

The photodetector 465 generates an electrical signal in response to the received optical signal and outputs the electrical signal. For example, the photodetector 465 may be a PIN (positive-intrinsic-negative) structure including a germanium (Ge) area. Although not illustrated in FIG. 4, a ring resonator may be additionally formed. The ring resonator is an element configured to filter a signal with a desired wavelength from the optical signals transmitted through the optical waveguide. The embodiments of the present disclosure are not limited to the above-mentioned optical components. A switch, a splitter, a heater, and the like may be formed in the photonic area in addition to the above-mentioned components.

The optical components may be classified into passive components and active components. The optical waveguide 450 and the grating coupler 455 are the passive components, and the optical modulator 460 and the photodetector 465 are the active components. To electrically connect the active components to the electronic components, connection terminals 470 and 475 are formed to penetrate the cladding layer 420 and be exposed to the top surface. For example, the connection terminals 470 and 475 is formed by a plurality of metal layers, and each of the connection terminals 470 and 475 has a shape in which contact pads are exposed to the top surface. Various structures may be used to electrically connect the active components to the electronic components without being limited to the structures of the connection terminals 470 and 475 of the present embodiment.

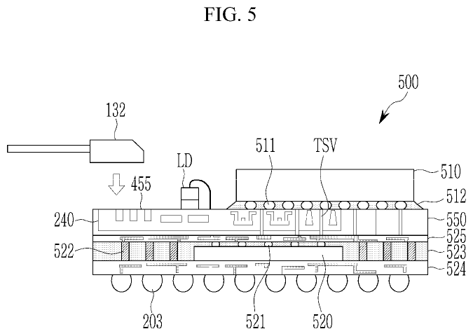

As described above, the example of the photonic area 240 including the optical components has been described with reference to FIG. 4. For example, each of the patterned silicon layer 410 defining an optical waveguide 450, a grating coupler 455, an optical modulator 460, and a photodetector 465, and connection terminals 470 and 475 may be provided in a photonic area, such as the photonic area 240 of FIG. 5 discussed further below. In the present disclosure, the photonic area 240 is defined as an area in which the optical components are formed, and the photonic area 240 is not limited to the above-mentioned structure.

FIG. 5 is a cross-sectional view of a silicon photonics package according to an example embodiment of the present disclosure.

A silicon photonics package 500 includes an interposer 550 including the photonic area 240. The photonic area 240 is formed at a top surface of the interposer 550. As described above, the photonic area 240 may be formed by a semiconductor process. In the drawings, the photonic area 240 constitutes a part of the top surface of the interposer 550, but the photonic area 240 may constitute the entire top surface of the interposer 550. The photonic area 240 may be optically isolated and may define at least a part of the top surface of the interposer 550. For example, at least one of the buried oxide layer 400 and the cladding layer 420 may be provided to optically isolate the photonic area 240. The interposer 550 includes the through silicon via TSV. The through silicon via TSV may be formed to penetrate the photonic area 240. The through silicon via TSV may be a plurality of through silicon vias TSVs, and each of the through silicon vias TSV may be formed to penetrate the photonic area 240.

Each of the patterned silicon layer 410 defining an optical waveguide 450, a grating coupler 455, an optical modulator 460, and a photodetector 465, and connection terminals 470 and 475 may be provided in the photonic area 240. Because the examples of the optical components formed in the photonic area 240 have been described with reference to FIG. 4, the details thereof are not repeated.

According to the present embodiment, at least a part of the top surface of the photonic area 240 is exposed and defines an exposure area. The optical coupler 132 is optically coupled directly to the exposure area. For example, the optical coupler 132 is attached onto the photonic area 240 and implements optical connection between the optical fiber array and the optical components. The optical coupler 132 is attached to the top surface of the photonic area 240 after the silicon photonics package is mounted on the system board or the like through the solder bump array 233. Because the optical coupler 132 has been described above, a repeated explanation thereof is omitted. The grating coupler 455 is disposed to receive the optical signal introduced from the optical coupler 132. The grating coupler 455 is formed at a position corresponding to the exposure area in which the optical coupler 132 is coupled in the photonic area 240.

The exposure area is an area that is not covered by other materials or elements on the top surface of the photonic area 240. In addition, the exposure area is an area in which the transmitted or received optical signal is transmitted directly to the photonic area 240 through the optical coupler 132. In the embodiment, the grating coupler 455 is positioned to be optically coupled to the optical coupler 132 through the exposure area. Alternatively, the grating coupler 455 may be optically coupled to the optical coupler 132 through the optical waveguide. In the present embodiment, the remaining area of the top surface of the photonic area 240, except for the area in which a first semiconductor chip 510 is mounted, is exposed.

The first semiconductor chip 510 is mounted on a top surface of the interposer 550, and a second semiconductor chip 520 is mounted on a bottom surface of the interposer. The light source element LD is attached to on the top surface of the photonic area 240. As described above, the light source element LD may be a semiconductor laser and may be attached to a groove formed in the photonic area 240 in a flip-chip manner.

The first semiconductor chip 510 is mounted on the top surface of the interposer 550 by a solder bump array 511, and a portion between the first semiconductor chip 510 and the top surface of the interposer 550 is filled with an underfill 512. The solder bump array 511 may be configured as a micro-solder bump array or a copper pillar bump array. The underfill 512 may surround the solder bump array 511, contacting the top surface of the interposer 550, the bottom surface of the first semiconductor chip 510, and side surfaces of each solder bump of the solder bump array 511. The first semiconductor chip 510 covers at least a part of the top surface of the photonic area 240. At least a part of the solder bump array 511 of the first semiconductor chip 510 is electrically connected to the active components of the optical components formed in the photonic area 240. To electrically connect the first semiconductor chip 510 and the active components, the connection terminals electrically connected to the active components are exposed to the top surface of the photonic area 240.

A redistribution layer 525 is formed on a bottom surface of the interposer 550, and the second semiconductor chip 520 is mounted on the redistribution layer 525 through a solder bump array 521. In addition, metal posts 522 are disposed on the redistribution layer 525 at the periphery of the second semiconductor chip 520. The second semiconductor chip 520 and the metal posts 522 are surrounded by the molding material 523, and a redistribution layer 524 is additionally formed to be facing the redistribution layer 525. A solder bump array 203, including a plurality of solder bumps, is formed on a bottom surface of the redistribution layer 524 and used to mount the silicon photonics package 500 on the system board or the like. The redistribution layer 524, the metal posts 522, the redistribution layer 525, and the through silicon vias TSVs implement electrical paths between the first semiconductor chip 510, the second semiconductor chip 520, and the external device.

The first semiconductor chip 510 and the second semiconductor chip 520 include the electronic components among the elements of the silicon photonics package 500. Because the examples of the electronic components have been described above, the electronic components are not described repeatedly.

The electronic components may include a logic circuit configured to amplify an electrical signal from the photodetector, output the amplified electrical signal to the outside, and operate the optical modulator in response to an electrical signal inputted from the outside. The first semiconductor chip 510 may include a part of the logic circuit, and the second semiconductor chip 520 may include the remaining part of the logic circuit. For example, as illustrated in FIG. 3, the electronic components may be classified depending on the function blocks thereof. That is, the logic circuit may include the trans-impedance amplifier 360 configured to convert an electric current signal from the photodetector into a voltage signal, the output driver 370 configured to output the converted electrical signal to the outside, the input buffer 330 configured to receive an electrical signal from the outside, the controller 340 configured to control the light source element, and the modulator driver 320 configured to operate the optical modulator. In some embodiments, the second semiconductor chip 520 may include the output driver 370 and the input buffer 330, and/or the first semiconductor chip 510 may at least include the trans-impedance amplifier 360, the modulator driver 320, and the controller 340. The trans-impedance amplifier 360 and the modulator driver 320 of the first semiconductor chip 510 may be electrically connected to the photodetector 465 and the optical modulator 460 through the top surface of the photonic area 240. In some embodiments, the second semiconductor chip 520 may further include a logic circuit configured to process the electrical signal from the output driver 370 and process the electrical signal to be inputted to the input buffer 330 in addition to the aforementioned electronic components.

The electronic components may be classified depending on the function blocks thereof. However, the single function block need not be necessarily completely included in the first semiconductor chip 510 or the second semiconductor chip 520. The elements, which constitute the logic circuit, may be separately included in the first semiconductor chip 510 and the second semiconductor chip 520. In some embodiments, the first semiconductor chip 510 includes a transistor array. For example, the transistor array may be a CMOS transistor array and/or a heterojunction bipolar transistor (HBT) array. For example, the first semiconductor chip 510 may be a chip including a transistor array part among the elements of a photonic integrated circuit (PIC) in the related art in which the transistor array is integrated in addition to the optical component.

Because the electronic components of the silicon photonics package 500 are divided into the first semiconductor chip 510 and the second semiconductor chip 520, it is possible to obtain advantages in that the process of manufacturing the semiconductor chip is simplified, a change in design of the logic circuit is more easily achieved, and utilization of the semiconductor chip is improved in comparison with the case in which all the electronic components are formed on the single semiconductor chip.

The silicon photonics package 500 according to the present embodiment may be manufactured by a chip-on-wafer (CoW) packaging technology. Therefore, it is possible to prevent a problem of warpage of a substrate during the mounting process and further miniaturize the silicon photonics package in comparison with the silicon photonics package manufactured by a chip-on-substrate (CoS) packaging technology.

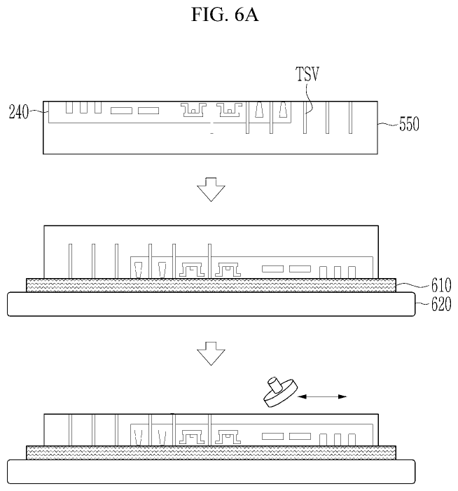

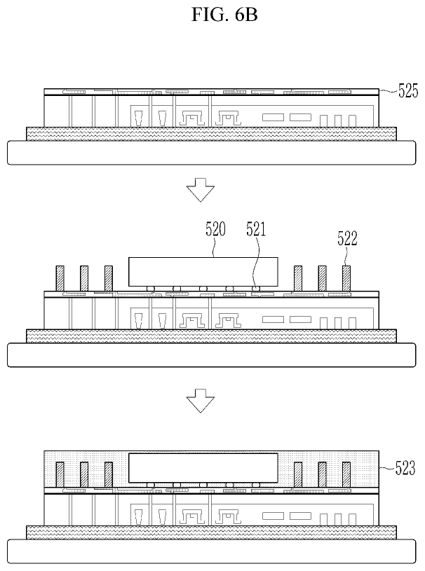

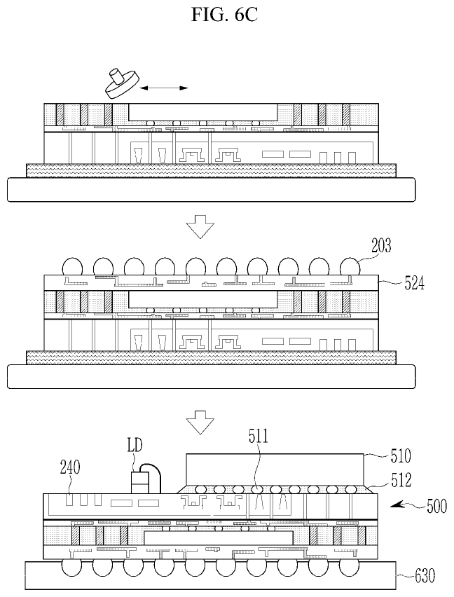

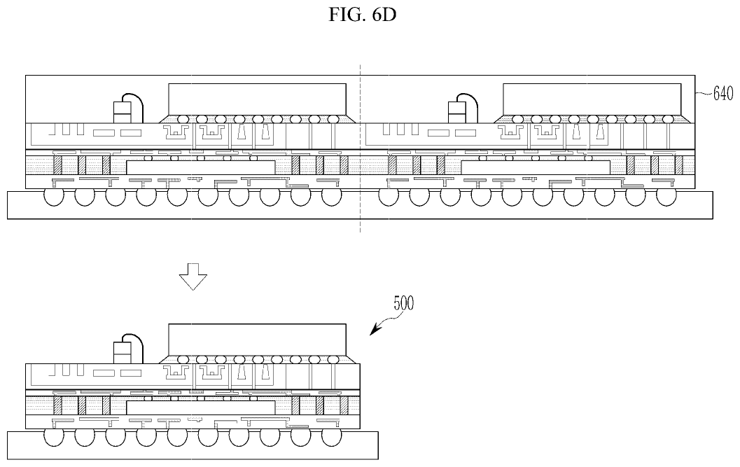

FIGS. 6A to 6D are process diagrams illustrating a method of manufacturing the silicon photonics package according to the example embodiment of the present disclosure.

Referring to FIG. 6A, there is provided the interposer 550 having the photonic area 240 and the through silicon vias TSVs formed on the top surface thereof. The photonic area and the optical components in the photonic area are formed by sequentially depositing the buried oxide layer 400 and the silicon layer on the top surface of the interposer 550 and patterning the silicon layer through the lithography process and the etching process. For example, the optical components may be embedded on the top surface of the interposer 550 by providing a buried oxide layer 400 on the top surface of the interposer 550, providing an optically isolated photonic area 240 by stacking a silicon layer 410 on the buried oxide layer 400, and providing the optical components by patterning the silicon layer 410. Because the structure of the photonic area 240 has been described above with reference to FIG. 4, the details thereof are not repeated. In some embodiments, a diameter of each of the through silicon vias may be 0.5 to 30 μm, a pitch of the through silicon vias may be 1 to 60 μm, and a height of each of the plurality of through silicon vias may be 5 to 300 μm.

The interposer 550 is flipped and then attached to a wafer 620 by a bonding member 610. For example, the wafer 620 may be a glass wafer. The bonding member 610 may be an adhesive tape, a bonding agent, or the like.

A bottom surface of the interposer 550, which is flipped after the interposer 550 is attached to the wafer 620, is planarized by a grinding process, and one end of each of the through silicon vias TSVs is exposed to the planarized surface.

Continuously referring to FIG. 6B, the redistribution layer 525 is formed by the lithography and the etching process on the bottom surface of the interposer to which one end of each of the through silicon vias TSVs is exposed.

The second semiconductor chip 520 is mounted on the redistribution layer 525, and the metal posts 522 are formed at the periphery of the second semiconductor chip 520. The second semiconductor chip 520 is mounted on the redistribution layer 525 through a solder bump array 521. In some embodiments, a diameter of each of the metal posts is 5 to 300 μm, a pitch of the metal posts is 10 to 600 μm, and a height of each of the metal posts is 50 to 1,000 μm.

Then, the second semiconductor chip 520 and the metal posts 522 on the redistribution layer 525 are surrounded by the mold material 523.

Continuously referring to FIG. 6C, a surface of the molding material 523 is planarized by a grinding process or the like. Then, the redistribution layer 524 is formed on the planarized surface by a lithography process and an etching process. One surface of the redistribution layer 525 is electrically connected to the metal posts 522, and the solder bump array 203 is formed on another surface of the redistribution layer 525.

Next, a mounting tape 630 is attached to a side at which the solder bump array 203 is formed, and the package, which has been manufactured to the current step, is separated from the wafer. The light source element LD is attached on the top surface of the photonic area, i.e., the opposite side to the side at which the mounting tape 630 is attached. The first semiconductor chip 510 is mounted on the top surface of the photonic area 240. For example, the first semiconductor chip 510 is mounted on the top surface of the interposer 550 by a solder bump array 511, and a portion between the first semiconductor chip 510 and the top surface of the interposer 550 is filled with an underfill 512.

The silicon photonics package 500 according to the example embodiment of the present disclosure is substantially manufactured by the above-mentioned process. In case that the plurality of silicon photonics packages 500 is formed on the interposer having a wafer size, a dicing process is additionally performed to singularize the silicon photonics packages 500. Referring to FIG. 6D, in case that the plurality of silicon photonics packages 500 are formed on the single interposer, a protective layer 640 is formed to cover all the plurality of silicon photonics packages 500, and then the dicing process is performed to singularize the silicon photonics packages 500. The protective layer 640 is removed, and the photonic area coupled to the optical coupler is exposed, such that the singularized silicon photonics package 500 may be used for a system assembling step.

Because the silicon photonics package 500 according to the present embodiment does not use a substrate, it is possible to prevent a problem of warpage of the substrate that occurs during a reflow process.

The silicon photonics package 500 converts an optical signal, which is received through the optical fiber array, into an electrical signal and transmits the electrical signal to the external device. The silicon photonics package 500 converts an electrical signal, which is received from the external device, into an optical signal and transmits the optical signal through the optical fiber array. The silicon photonics package 500 may be used for a device and system having the function of transmitting and receiving data, and the application field thereof is very wide. Representatively, the silicon photonics package may be used for the switch package of the data center.

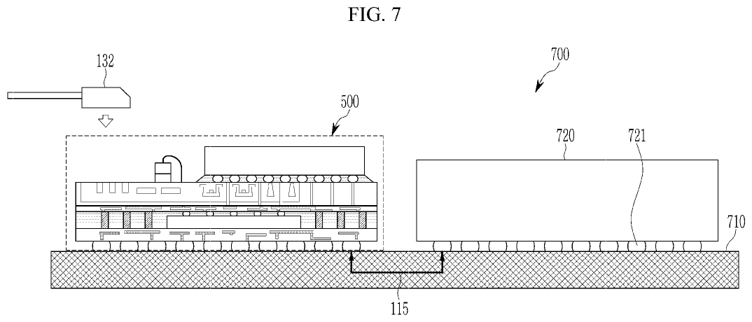

FIG. 7 is a partial cross-sectional view of the switch package according to an example embodiment of the present disclosure.

A switch package 700 is installed on a data transmission path in the data center and includes a switch ASIC chip 720 and the silicon photonics package 500.

In the present embodiment, in the switch package 700, the switch ASIC chip 720 is mounted on a substrate 710 by a solder bump array 721. In addition, the silicon photonics package 500 and the switch package 700 are mounted on the same substrate 710. The switch ASIC chip 720 and the silicon photonics package 500 may be electrically connected to each other by a conductive circuit formed in the substrate 710 or formed on the substrate 710. For example, the switch ASIC chip 720 and the silicon photonics package 500 may be electrically connected to each other through electrical signal paths 115 formed by conductive connection members in a substrate 710 and/or on the substrate 710. The photonic area 240 of the silicon photonics package 500 includes the exposure area to which the optical coupler 132 may be attached.

FIG. 7 illustrates the single silicon photonics package 500. However, referring to FIG. 1, the plurality of silicon photonics packages 500 may be disposed on the same substrate 710 and provided at the periphery of the switch ASIC chip 720. For example, a switch ASIC chip 720 may be provided at a center region of substrate 710, and a plurality of silicon photonics packages 500 may be disposed on the substrate 710 to surround the switch ASIC chip 720 at a periphery of the substrate 710. In the present embodiments, because the silicon photonics package 500 is small in scale, the switch package 700 including a larger number of silicon photonics packages 500 may be manufactured. Alternatively, as the small-scale silicon photonics package 500 is used, a size of the switch package 700 may be reduced.

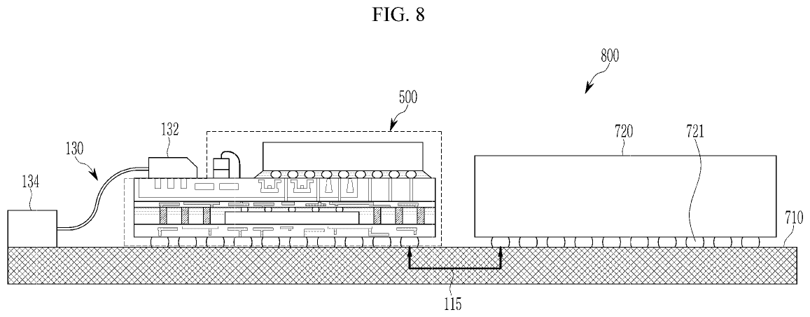

FIG. 8 is a cross-sectional view of a switch package according to another example embodiment of the present disclosure.

A switch package 800 has the same structure as the switch package 700 in FIG. 7, except for the optical fiber interface 130. Therefore, for convenience of description, only the optical fiber interface 130 is described.

A process of attaching the optical coupler 132 to the photonic area of the silicon photonics package 500 is a precise process. The process of attaching the optical fiber array to the silicon photonics package 500 is required at the time of assembling the switch package 700 to the system board or the like of the data center. However, the process requires high precision.

In the present embodiment, the switch package 800 includes the optical fiber interface 130. The optical fiber interface 130 includes the optical coupler 132 provided at one end thereof, and an optical connector 134 provided at the other end thereof. The optical coupler 132 is attached to the silicon photonics package 500 during the process of manufacturing the switch package 800. Because the optical coupler 132 has been described above, a detailed description thereof is not repeated.

In the present embodiment, like a plug type, the optical connector 134 has a structure that is easily connected or disconnected but does not require a high-precision coupling process. The optical connector 134 may include a structure for positioning. The optical connector 134 may be a standard fiber ferrule. The optical connector 134 may be fixed onto the substrate 710, but the present disclosure is not necessarily limited thereto. The optical connector 134 and the optical coupler 132 may be optically connected to each other through the optical fiber array. Alternatively, the optical connector 134 and the optical coupler 132 may be optically connected to each other by a polymer waveguide having a flexible ribbon shape. In some embodiments, the optical connector 134 and the optical coupler 132 may be integrated.

The switch package 800 according to the present embodiment is advantageous in that a process of connecting the optical fiber array is simple at the time of assembling the system.

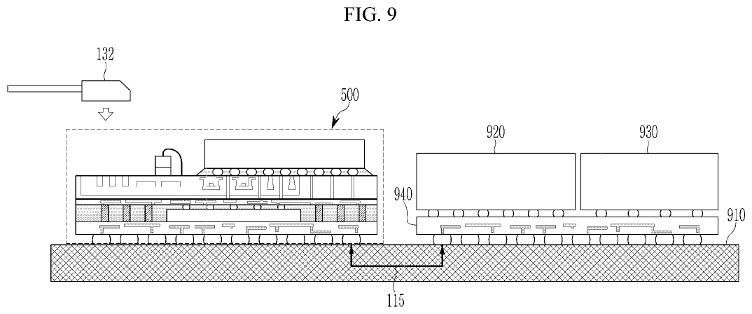

The silicon photonics package according to the embodiments of the present disclosure may be applied to various fields. FIG. 9 is a schematic cross-sectional view of a device according to an example embodiment of the present disclosure.

In the present embodiment, a data processing device includes a processor chip 920 and a memory chip 930. Therefore, this device serves as a computing device that computes and processes data.

Referring to FIG. 9, the processor chip 920 and the memory chip 930 are mounted together on an interposer 940. For example, the processor chip 920 and the memory chip 930 may be mounted on the interposer 940 with solder ball arrays. A package substrate may be used instead of the interposer 940. The processor chip 920 and the memory chip 930 may have a three-dimensional layered structure.

The silicon photonics package 500 is also mounted on a host board 910. The silicon photonics package 500 is electrically connected to the processor chip 920 through a conductive path formed on the host board 910 or in the host board 910. For example, the processor chip 920 and the silicon photonics package 500 may be electrically connected to each other through electrical signal paths 115 formed by conductive connection members in the host board 910 and/or on the host board 910.

The silicon photonics package 500 is substituted for a communication module connected to a network such as the Internet in the related art. Because the device is equipped with the silicon photonics package 500, the device may transmit or receive data to or from another device through optical communication implemented by the optical fiber array. The device may have high performance because the device may transmit and receive a large amount of data at high speed. Therefore, the device may be used for a high-performance computing (HPC), artificial intelligence and machine (AI & ML), and hyper-scale data sensor.

Although the embodiments of the present disclosure have been described in detail above, the right scope of the present disclosure is not limited thereto, and it should be construed that many variations and modifications made by those skilled in the art using the basic concept of the present disclosure, which is defined in the following claims, will also belong to the right scope of the present disclosure.

What is claimed is:

1. A silicon photonics package comprising:
an interposer comprising embedded optical components and a plurality of through silicon vias (TSVs);
a light source element optically connected to the optical components;
a first semiconductor chip mounted on a top surface of the interposer;
a first redistribution layer provided on a bottom surface of the interposer;
a second semiconductor chip mounted on the first redistribution layer;
a second redistribution layer disposed to be facing the first redistribution layer with the second semiconductor chip interposed therebetween, the second redistribution layer being electrically connected to the first redistribution layer;
conductive metal posts provided between the first redistribution layer and the second redistribution layer;
a mold material with which a space between the first redistribution layer and the second redistribution layer is filled; and
a solder bump array provided on a bottom surface of the second redistribution layer,
wherein the top surface of the interposer comprises an exposure area to which an optical fiber array is directly attached, wherein an optical signal is directly transmitted between the optical components and the optical fiber array through the exposure area, and
wherein the first semiconductor chip and the second semiconductor chip comprise electronic components configured to perform electronic processing for transmitting a signal between the optical components and an external device.

2. The silicon photonics package of claim 1, wherein:
the interposer comprises a photonic area provided at a top surface thereof,
the photonic area is optically isolated and defines at least a part of the top surface of the interposer,
the optical components are provided in the photonic area, and
the exposure area is at least a part of the photonic area.

3. The silicon photonics package of claim 2, wherein:
connection terminals are provided on a top surface of the photonic area and electrically connected to some of the optical components,
the first semiconductor chip is mounted to cover at least a part of the photonic area, and
the first semiconductor chip is electrically connected to the connection terminals through at least a part of the solder bump array.

4. The silicon photonics package of claim 3, wherein:
the first semiconductor chip is configured to receive an electrical signal from some of the optical components and transmit the received electrical signal to the second semiconductor chip through the plurality of through silicon vias (TSV).

5. The silicon photonics package of claim 2, wherein:
the optical components comprise a grating coupler, an optical modulator, an optical waveguide, and a photodetector.

6. The silicon photonics package of claim 5, wherein:
the electronic components comprise a logic circuit configured to amplify an electrical signal from the photodetector to output the electrical signal to an outside, and operate the optical modulator in response to an electrical signal inputted from the outside.

7. The silicon photonics package of claim 6, wherein:
the first semiconductor chip comprises a part of the logic circuit, and the second semiconductor chip comprises a remaining part of the logic circuit.

8. The silicon photonics package of claim 7,
wherein the logic circuit comprises a trans-impedance amplifier configured to convert the electrical signal from the photodetector into a voltage signal, an output driver configured to output the converted electrical signal to the outside, an input buffer configured to receive an electrical signal from the outside, a controller configured to control the light source element, and a modulator driver configured to operate the optical modulator, and
wherein the second semiconductor chip at least comprises the output driver and the input buffer.

9. The silicon photonics package of claim 2,
wherein the photonic area comprises a buried oxide layer, and a silicon layer stacked on the buried oxide layer, and
wherein the optical components are provided by patterning the silicon layer.

10. The silicon photonics package of claim 9, wherein:
the first semiconductor chip comprises a transistor array.

11. The silicon photonics package of claim 1, wherein:
a diameter of each of the plurality of through silicon vias is 0.5 to 30 μm,
a pitch of the plurality of through silicon vias is 1 to 60 μm, and
a height of each of the plurality of through silicon vias is 5 to 300 μm.

12. The silicon photonics package of claim 1, wherein:
a diameter of each of the metal posts is 5 to 300 μm,
a pitch of the metal posts is 10 to 600 μm, and
a height of each of the metal posts is 50 to 1,000 μm.

13. The silicon photonics package of claim 1, wherein:
the light source element is mounted on a top surface of a photonic area.

14. The silicon photonics package of claim 1, wherein:
the light source element is disposed in a groove provided in the interposer.

15. A method of manufacturing a silicon photonics package, the method comprising:
providing optical components embedded at a top surface of an interposer and providing a plurality of through silicon vias (TSVs) in the interposer;
flipping the interposer and bonding the interposer to a wafer by means of a carrier tape;
grinding a bottom surface of the interposer and providing a first redistribution layer on the bottom surface of the interposer;
providing metal posts on the first redistribution layer and attaching a second semiconductor chip;
providing a molding material to surround the metal posts and the second semiconductor chip;
grinding a surface of the molding material and providing a second redistribution layer on the surface of the molding material;
providing a solder bump array on the second redistribution layer;
attaching a mounting tape to a side at which the solder bump array is provided and removing the carrier tape; and
attaching a first semiconductor chip and a light source element onto the top surface of the interposer,
wherein at least some of the optical components are configured to directly transmit or receive an optical signal to or from an optical fiber array through a part of the top surface of the interposer, and
wherein the first semiconductor chip and the second semiconductor chip comprise electronic components configured to perform electronic processing for transmitting a signal between the optical components and an external device.

16. The method of claim 15, wherein the providing of the optical components embedded at the top surface of the interposer comprises:
providing a buried oxide layer on the top surface of the interposer and providing an optically isolated photonic area by stacking a silicon layer on the buried oxide layer; and
providing the optical components by patterning the silicon layer.

17. The method of claim 16, wherein:
the first semiconductor chip comprises a transistor array.

18. The method of claim 15,
wherein a plurality of silicon photonics packages are manufactured at a wafer level, and
wherein the method further comprises:
providing a protective layer configured to cover the top surface of the interposer after the removing of the carrier tape;
singularizing the silicon photonics package by dicing; and
removing the protective layer.

19. A switch package comprising:
a substrate;
a switch application specific integrated circuit (ASIC) chip mounted at a central portion of the substrate; and
a plurality of optical transceivers mounted at a periphery of the switch ASIC chip,
wherein the switch ASIC chip and the plurality of optical transceivers are electrically connected through an electrical circuit of the substrate,
wherein the optical transceivers each comprise:
an interposer comprising embedded optical components and a plurality of through silicon vias (TSVs);
a light source element optically connected to the optical components;
a first semiconductor chip mounted on a top surface of the interposer;
a first redistribution layer provided on a bottom surface of the interposer;
a second semiconductor chip mounted on the first redistribution layer;
a second redistribution layer disposed to be facing the first redistribution layer with the second semiconductor chip interposed therebetween, the second redistribution layer being electrically connected to the first redistribution layer;
conductive metal posts provided between the first redistribution layer and the second redistribution layer;
a mold material with which a space between the first redistribution layer and the second redistribution layer is filled; and
a solder bump array provided on a bottom surface of the second redistribution layer and electrically connected to the substrate,
wherein the top surface of the interposer comprises an exposure area to which an optical fiber array is directly attached, wherein an optical signal is directly transmitted between the optical components and the optical fiber array through the exposure area, and
wherein the first semiconductor chip and the second semiconductor chip comprise electronic components configured to perform electronic processing for transmitting a signal between the optical components and an external device.

20. The switch package of claim 19, further comprising:
an optical fiber interface comprising an optical coupler optically connected to the exposure area of the interposer, and an optical connector to which the optical fiber array is connected.
